(19) United States
(12) Patent Application Publication
(10) Pub. No.: US 2006/0232992 A1
(43) Pub. Date: Oct. 19, 2006

(54) Circuit arrangement for ac driving of organic diodes

(75) Inventors: Dietrich Bertram, Aachen (DE); Hans-Helmut Bechtel, Roetgen (DE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., BA Eindhoven (NL)

(21) Appl. No.: 10/567,395

(22) PCT Filed: Jul. 30, 2004
(86) PCT No.: PCT/IB04/51338

§ 371 Date: Feb. 7, 2006

(30) Foreign Application Priority Data
Aug. 12, 2003 (EP) 03102507.5

(51) Int. Cl. H01L 33/00

(52) U.S. Cl. 362/555

(57) ABSTRACT

Organic light emitting devices emit light when operated with low dc voltage forward bias. According to the present invention, a space saving circuit arrangement of organic light emitting devices is disclosed, the circuit arrangement emitting light on both the positive and the negative cycle of an ac driving voltage. Furthermore a method is disclosed for producing the circuit arrangement on a substrate. Advantageously, the present invention allows for high voltage ac driving of organic light emitting devices or organic diodes without the need of additional rectifying electronics.

The present invention relates to the field of organic diodes. More particularly, the present invention relates to a circuit arrangement of organic diodes and methods for producing a circuit arrangement of organic light emitting devices.

Among the most commonly known electroluminescent systems are anorganic light emitting devices (LEDs), which are based on crystalline semi-conductor materials grown on wafer substrates in different material systems. This form of electro-luminescent devices was discovered in the 1960s and has been developed to a remarkable degree.

The entry of these LEDs into the lighting market came with GaN based semi-conductors emitting blue light.

Alternatively, organic semi-conductors have been researched for displays for about 15 years. Organic light emitting devices (OLEDs) are light emitting devices that use organic electro-luminescent materials excited by electric current to emit light A plurality of OLEDs can be arranged in an array, for example, to form a display.

OLEDs enjoy several advantages over light emitting devices formed with other technologies. Some of the advantages of OLEDs include high efficiency, the ability to emit light from a relatively large area, the use of low cost materials, the ability to use a wide variety of substrates, a wide viewing angle, low voltage operation, direct emission and high reliability. Furthermore, OLEDs are very flat and emit diffusive light.

U.S. Pat. No. 6,274,980 discloses a stacked organic light emitting device (SOLEDs), comprising a vertical stack of OLEDs, i.e. a stacked OLED device, in which the OLEDs in the stack simultaneously emit light of the same colour. In general, OLEDs typically generate light under dc type forward bias of 2 to 20 V. This has the consequence that in a lighting device, electronic gear, such as, for example, a transformer and a rectifier have to be used whenever the device is driven from an ac voltage source.

It is an object of the present invention to provide for an operation of organic diodes with an ac driving voltage.

According to an exemplary embodiment of the present invention as set forth in claim 1, the above object may be solved by electrically contacting the organic diodes to electrodes in such a way that: on a positive cycle of an ac driving voltage, the first organic diode is operated in a forward direction and the second organic diode is reversely biased and on a negative cycle of the ac driving voltage, the first organic diode is reversely biased and the second organic diode is operated in a forward direction.

In other words, according to this exemplary embodiment of the present invention, a circuit arrangement of organic diodes for ac driving of the organic diodes is provided by electrically connecting the organic diodes in an anti-parallel arrangement to electrodes in such a way that on a positive cycle of an ac driving voltage, the first organic diode is driven in current flow direction and the second organic diode blocks the current flow; on a negative cycle of the ac driving voltage, which is electrically connected to the electrodes, the first organic diode blocks the current flow and the second organic diode is driven in current flow direction.

Advantageously, according to this exemplary embodiment of the present invention, no rectification of the driving voltage is needed when operating the organic diodes.

It should be understood that more than one first organic diode and more than one second organic diode can be implemented in the above mentioned circuit arrangement according to the present invention. The first organic diodes may be electrically connected in series, forming a first serial array and the second organic diodes may be electrically connected in series, forming a second serial array. By electrically connecting the first and the second serial arrays in an anti-parallel arrangement to the first and the second electrodes, a circuit arrangement of organic diodes for ac driving of the organic diodes is provided according to an exemplary embodiment of the present invention.

According to another exemplary embodiment of the present invention as set forth in claim 2, the first and second organic diodes are first and second organic light emitting devices. The circuit arrangement may be implemented in a display, a vehicle, a television, a computer, a printer, a screen, a sign, a telecommunications device or a telephone. Advantageously, there will be emission of light at all times, even if the circuit arrangement according to claim 2 is driven by an ac driving voltage. The circuit arrangement is chosen such that the first light emitting organic diodes illuminate during the first half cycle of the ac voltage source and the second light emitting organic diodes illuminate during the second half cycle of the ac voltage source. By using frequencies above 30 Hz, no flickering is visible from the light source and no driving electronics is necessary to operate from ac lines.

Additionally, by connecting several organic light emitting devices in series, the overall breakdown voltage is increased by a factor proportional to the number of serially connected organic light emitting devices. Therefore, higher ac driving voltages may be applied to the circuit arrangement of organic light emitting devices.

According to another exemplary embodiment of the present invention as set forth in claim 3, the circuit arrangement comprises an array of first and second organic light emitting devices, the array emitting light on the negative and the positive cycle of the ac driving voltage. According to an aspect of the exemplary embodiment of the present invention, the first and the second organic light emitting devices each comprise a lower side and an upper side. According to the exemplary embodiment of the present invention, the first and second organic light emitting devices are stacked vertically above each other and are stacked such that the forward directions of the first and the second organic light emitting devices point in the same direction. The lower side of the first organic light emitting device and the upper side of the second organic light emitting device are electrically contacted to a first electrode. One the other hand, the upper side of the first organic light emitting device and the lower side of the second organic light emitting device are electrically contacted to a second electrode. An advantage of stacking the first and second organic light emitting devices vertically is that it may save space on a substrate surface, the substrate being used for carrying the first and second organic light emitting devices.

Advantageously, by stacking the first and second organic light emitting devices, the emission intensity of the emitted light is increased. In the above context, emission intensity refers to the number of emitted photons per area.

According to another exemplary embodiment of the present invention as set forth in claim 4, the first and second organic light emitting devices comprise light emitting layers, which emit light of a colour selected from the group of colours consisting of blue, green, yellow and red. Again, it should be understood that in the circuit arrangement according to the present invention, more than one first and more than one second organic light emitting device may be incorporated. Therefore, it is possible to include organic light emitting devices of different colours, for example, of the colours red, green and blue. By arranging red, green and blue organic light emitting devices in a circuit arrangement according to the present invention, a light source emitting white light may be realized. According to another aspect of the present invention, blue and yellow organic light emitting devices may be implemented in the circuit arrangement. The mixing of blue and yellow light may lead to white light.

According to another exemplary embodiment of the present invention as set forth in claim 5, one first organic light emitting device and one second organic light emitting device form a component. According to an aspect of the present invention, a plurality of components is arranged vertically and the first electrode of the each component is electrically connected to the second electrode of the next upper component in such a way that all components are connected in series. According to another aspect of the present invention, the plurality of components is arranged horizontally and the first electrode of each component is electrically connected to the second electrode of an adjacent component in such a way that all components are connected in series. By serially connecting the plurality of components, the ac driving voltage may be increased without damaging one or more components of the plurality of components.

According to another exemplary embodiment of the present invention as set forth in claim 6, a method for producing a circuit arrangement of organic light emitting devices is provided, the circuit arrangement being arranged on a substrate, the method comprising the steps of depositing a plurality of layers of different materials on the substrate, the first layer comprising α-NPD, the second layer comprising CBP: FlIrpic, the third layer comprising BAlq, the fourth layer comprising Bphen: Cs, the fifth layer comprising Ag, the sixth layer comprising α-NPD, the seventh layer comprising CBP: Firpic, the eighth layer comprising BAlq, the ninth layer comprising Bphen: Cs, and the tenth layer comprising Al. Advantageously, a circuit arrangement produced by the method according to claim 6 provides a stack of organic light emitting devices which emits white light and can be driven by an ac driving voltage.

It may be seen as the gist of an exemplary embodiment of the present invention that a circuit arrangement of organic light emitting devices can be operated at ac voltages, even at high ac voltages with an amplitude above the breakdown voltage of each individual organic light emitting device. Furthermore, the circuit arrangement emits light on both the negative and the positive cycle of the ac driving voltage.

These and other aspects of the present invention will become apparent from and elucidated with reference to the embodiments described hereinafter.

Exemplary embodiments of the present invention will be described in the following, with reference to the following drawings:

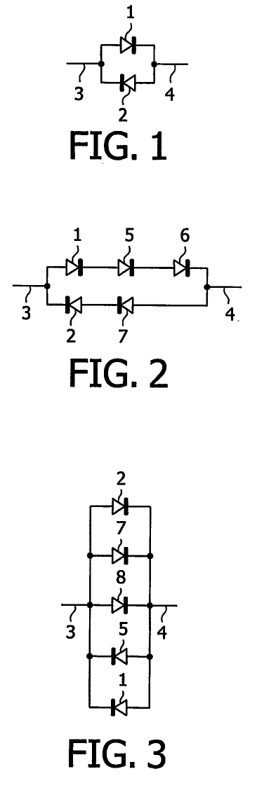

FIG. 1 shows a schematic diagram of a circuit arrangement according to an exemplary embodiment of the present invention.

FIG. 2 shows a schematic diagram of a circuit arrangement of organic diodes according to another exemplary embodiment of the present invention.

FIG. 3 shows a schematic diagram of another circuit arrangement of organic diodes according to another exemplary embodiment of the present invention.

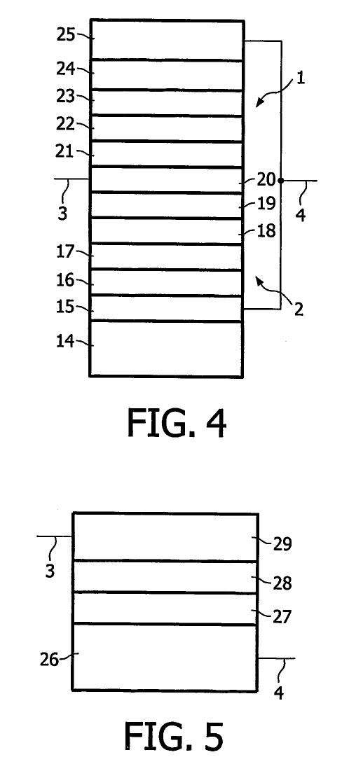

FIG. 4 shows a diagrammatic representation of a circuit arrangement of stacked organic light emitting devices according to an exemplary embodiment of the present invention and produced by a method according to an exemplary embodiment of the present invention.

FIG. 5 shows an exemplary embodiment of an organic light emitting device according to an exemplary embodiment of the present invention and produced by a method according to an exemplary embodiment of the present invention.

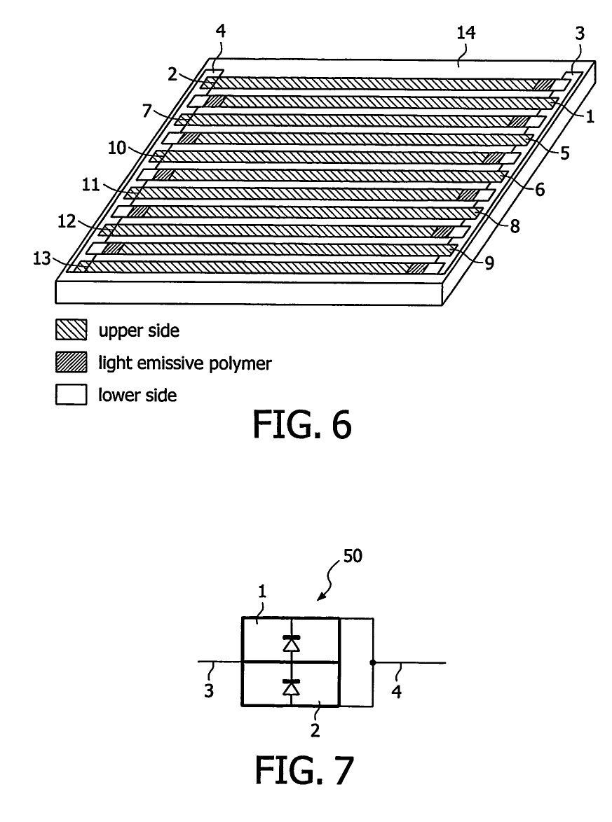

FIG. 6 shows a schematic view of the circuit arrangement of organic light emitting devices according to an exemplary embodiment of the present invention.

FIG. 7 shows a schematic diagram of a circuit arrangement of organic light emitting devices according to an exemplary embodiment of the present invention.

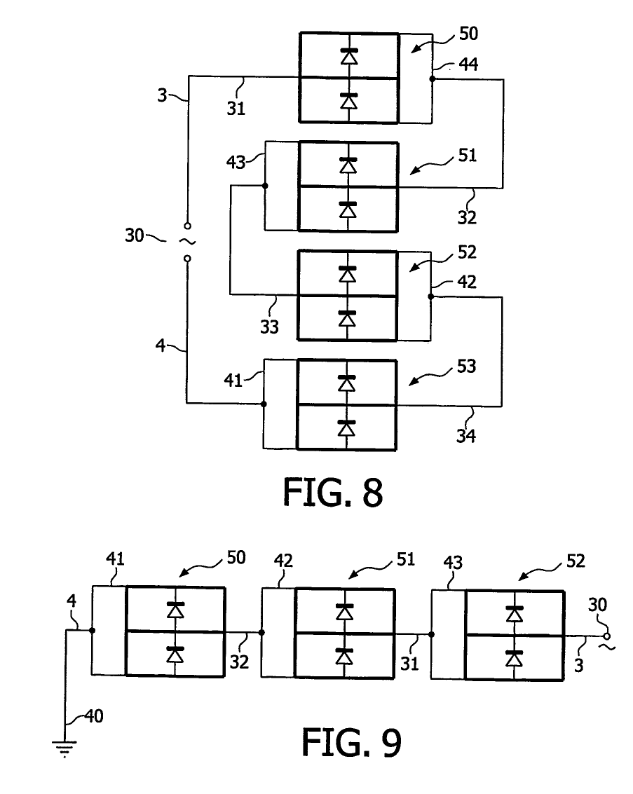

FIG. 8 shows a schematic diagram of a circuit arrangement of organic light emitting devices according to another exemplary embodiment of the present invention.

FIG. 9 shows a schematic diagram of a circuit arrangement of organic light emitting devices according to an exemplary embodiment of the present invention.

For the description of FIGS. 1-9, the same reference numerals are used for the same or corresponding elements.

FIG. 1 shows a schematic representation of a circuit arrangement of organic diodes according to an exemplary embodiment of the present invention. A first organic diode 1 and a second organic diode 2 are connected to a first electrode 3 and a second electrode 4 in an anti-parallel manner, such that the first organic diode 1 is operated in a forward direction and the second organic diode 2 is reversely biased, when the circuit arrangement is driven by a positive cycle of an ac driving voltage. On the other hand, when driven by a negative cycle of the ac driving voltage, the first organic diode 1 is reversely biased and the second organic diode 2 is operated in a forward direction.

It should be noted that the organic diodes 1 and 2 can be positioned on a substrate (the substrate is not shown in the Fig.). In this case, the circuit arrangement can be understood as an integrated circuit on the substrate.

FIG. 2 shows a schematic diagram of another exemplary embodiment of the present invention, wherein a plurality of first organic diodes 1, 5 and 6 are electrically connected in series and another plurality of organic diodes 2 and 7 are electrically connected in series, the first plurality forming a first serial array, the second plurality forming a second serial array. The first and second serial connections are connected in an anti-parallel arrangement. First electrode 3 and second electrode 4 are connected to the anti-parallel arrangement of the first and second serial array of organic diodes. Application of an ac driving voltage to the first or second electrode causes a current to flow through either the first serial array of organic diodes 1, 5 and 6 or the second serial array of organic diodes 2 and 7. A combination of serial and anti-parallel arrangement of organic diodes as depicted in FIG. 2 has the advantage that the circuit arrangement can be driven with an ac driving voltage in the sense that on a positive cycle of the ac driving voltage, one of either first or second serial arrays of organic diodes is driven in a forward direction. On the other hand, on a negative cycle of the ac driving voltage, the other one of either first or second serial arrays of organic diodes is driven in a forward direction. The other advantage of the circuit arrangement as depicted in FIG. 2, is that due to the serial arrangement of a plurality of organic diodes, the overall breakthrough voltage is increased by a factor proportional to the number of serially connected organic diodes.

In the circuit arrangement of organic diodes depicted in FIG. 3, first electrode 3 is connected to a first array of first organic diodes 2, 7 and 8 and a second array of second organic diodes 5 and 1. The other side of the first and second arrays is connected to second electrode 4. First organic diodes 2, 7 and 8 are connected in parallel, each of the forward directions pointing from the first electrode 3 to the second electrode 4. The second organic diodes 5 and 1 are also connected in parallel, but their forward directions point from second electrode 4 to first electrode 3. It should be understood that combinations can be made of the described exemplary embodiments depicted in FIGS. 1 to 3, leading to a huge set of different circuit arrangements, according to the present invention.

FIG. 4 shows a schematic view of a circuit arrangement of first and second organic light emitting devices according to an exemplary embodiment of the present invention. The circuit arrangement comprises a first 1 and a second 2 organic light emitting device, wherein the first organic light emitting device 1 is arranged on top of the second light emitting device 2. According to an exemplary embodiment of the present invention, the circuit arrangement is arranged on the substrate 14. The substrate 14 may be a transparent glass substrate. In order to keep impurities from the glass from migrating into the structure, a SiO₂ layer may be deposited on top of the surface of the substrate 14. Deposition of the SiO₂ layer may be achieved by sputtering a layer of indium tin oxide (ITO) 15 on top of the SiO₂ layer. This deposition may be achieved by sputtering.

The ITO 15 is typically annealed in order to achieve high conductivity, which is necessary to be able to distribute high current densities over large areas homogeneously. A lower electrode structure is edged into the ITO layer 15, the lower electrode structure being adapted according to the present invention. Since even annealed ITO 15 may still have insufficient conductivity metal shunt lines may be deposited on top of the structured lower electrodes. The organic layers are deposited on top of the ITO layer 15 and the metal shunt lines.

According to an exemplary embodiment of the present invention, the method for depositing the organic layers comprises the steps of: depositing a first layer 16 on the structured electrode, the layer comprising α-NPD (Bis[N-(1-naphthyl)-N-phenyl]benzidine); in a following step a second layer 17 is deposited on the first layer 16, the second layer comprising CBP: FIrpic (CBP:Flrpic refers to 4,4f-N, Nf-dicarbazole-biphenyl, which is host doped by a phosphorescent iridium complex bis(2-(4,6-difluorophenyl)pyridyl-N, C2) iridium(III) picolinate (Flrpic); in a third step, a third layer 18 is deposited on the second layer 17, the third layer comprising BAlq (2-methyl-8-quinolinolato N1,O8) aluminium); in a fourth step, a fourth layer 19 is deposited on the third layer 18, the fourth layer 19 comprising Bphen: Cs (4,7-diphenyl-1, 10phenanthroline host doped by caesium); in a fifth step, a fifth layer 20 is deposited on the fourth layer 19, the fifth layer comprising Ag; in a sixth following step, a sixth layer 21 is deposited on the fifth layer 20, the sixth layer 21 comprising a-NPD; following that, a seventh layer 22 is deposited on the sixth layer 21, the seventh layer 22 comprising CBP: FIrpic; in a following eighth step, an eighth layer 23 is deposited on the seventh layer 22, the eighth layer 23 comprising BAlq; in a ninth step, a ninth layer 24 is deposited on the eighth layer 23, the ninth layer 24 comprising Bphen: Cs.

In an exemplary embodiment of the method for producing a circuit arrangement of organic light emitting devices according to the present invention, the device is completed by an upper metal electrode 25, which typically consists of a low work function metal, such as, for example, Ba, Ca or Mg followed by a final layer which may comprise Al or Ag. It should be clear that other materials may be used for the upper electrode 25, e.g. Li-compounds such as LiF or Cs-doped layers compared to an ITO covered glass substrate where the metal upper electrode 25 is thick and mirror-like. This leads to a mirror-like appearance of the device in its off-state.

In an alternative embodiment of the present invention, a transparent upper electrode structure 25 may be used, the transparent upper electrode 25 may either consist of a sputtered ITO layer or a stacked structure of a very thin metal layer and a dielectric matching layer. The thin metal layer may comprise Ag and the dielectric matching layer comprises a high refractive index. Therefore, the final device may be transparent or translucent, depending on the absorption spectrum of the organic layers being used.

Patterning of the lower electrode arranged directly on the surface of the substrate may be based on standard photolithography and etching. The deposition of the metallic upper electrode 25 in FIG. 4 and 29 in FIG. 5 may be based on evaporation or sputtering. The deposition of the organic diode layers may be based on evaporation through a shadow mask or on wet coating or printing. In an exemplary embodiment of the present invention, the circuit arrangement of organic light emitting devices may be hermetically sealed. The hermetic seal may be achieved by depositing a glass or metal lid with getters, which are glued to the device with an organic glue.

In another exemplary embodiment of the present invention, a transparent cathode is used and an opaque substrate. The opaque substrate may be a metal sheet or a metal foil. This approach may have several advantages over the conventional device structure. First, the substrate is supposed to be much cheaper, resulting in a cost reduction of the final product; additionally, using a metal as a substrate, a better heat conduction effectively cools the device and thus increases the lifetime and the efficiency. Additionally, by using metal foils as substrates, a flexible device can be obtained. In an eleventh step, the individual organic light emitting devices are electrically contacted to first and second electrodes 3 and 4 respectively.

In an exemplary embodiment of the method according to the present invention, the thickness of the first layer is approximately 30 nm, the thickness of the second layer is approximately 80 nm, the thickness of the third layer is approximately 30 nm, the thickness of the fourth layer is approximately 5 nm, the thickness of the fifth layer is approximately 10 nm, the thickness of the sixth layer is approximately 30 nm, the thickness of the seventh layer is approximately 80 nm, the thickness of the eighth layer is approximately 30 nm and the thickness of the ninth layer is approximately 5 nm.

According to another exemplary embodiment of the method of the present invention, the dopant concentration of the second layer is approximately 8 % and the dopant concentration of the seventh layer is approximately 8 %.

FIG. 5 depicts a schematic view of a circuit arrangement of organic light emitting devices produced by a method according to the present invention. The circuit arrangement may be arranged on a transparent substrate, the substrate comprising a structured electrode, the method comprising the steps of covering the structured transparent electrode by a layer of PDOT 26 (poly(3,4-ethylenedioxythiophene) with a thickness of approximately 150 nm. The PDOT layer 26 may be deposited on the structured transparent electrode by spin coating. In a second step, a second layer, comprising a light emissive polymer 27 is deposited, with a thickness of approximately 70 nm on top of the PDOT layer 26. According to an exemplary embodiment of this aspect of the present invention, the light emissive polymer 27 comprises PPV (poly phenylene vinylene). In a third step, a third layer 28 is deposited on the second layer 27, wherein the third layer 28 is structured according to the structured transparent electrode, which is arranged on the substrate. The third layer 28 comprises Ba, with a thickness of approximately 5 nm. On top of the third layer 28, a fourth layer 29 is deposited and structured according to the transparent electrode. The fourth layer 29 comprises aluminium and has a thickness of approximately 150 nm and acts as an upper electrode. In an additional step, the organic light emitting device is electrically contacted to first and second electrodes 3 and 4 respectively.

FIG. 6 shows a circuit arrangement of an array of organic light emitting devices according to an exemplary embodiment of the present invention. The individual organic light emitting devices shown in FIG. 6 are deposited on top of a substratel4, the substrate 14 being transparent and comprising a structured electrode, which is not depicted in FIG. 6. In an exemplary embodiment of this aspect of the present invention, the structured electrode is transparent and covered by a spin-coated film of PDOT, with a thickness of approximately 150 nm. The individual organic light emitting devices, which are deposited on the PDOT layer, are described in FIG. 5 in more detail. The organic light emitting devices are either first organic light emitting devices 1, 5, 6, 8 and 9 or second organic light emitting devices 2, 7, 10, 11, 12 and 13. Each first and second organic light emitting device comprises a lower side and an upper side. Sandwiched between each lower and upper side is a light emissive polymer layer. In FIG. 6, the lower sides of the first and second organic light emitting devices are represented by white colour, the upper sides by dark gray colour, the light emitting polymer by black colour.

The upper side of the first organic light emitting devices 1, 5, 6, 8 and 9 are electrically connected to a first electrode 3 and the lower sides of the first organic light emitting devices 1, 5, 6, 8 and 9 are electrically connected to a second electrode 4. The upper sides of second organic light emitting devices 2, 7, 10, 11, 12 and 13 are electrically connected to the second electrode 4 and the lower sides of the second organic light emitting devices 2, 7, 10, 11, 12 and 13 are electrically connected to the first electrode 3. Applying a dc voltage to the system, the amplitude of the dc voltage lying above the threshold voltage of each organic light emitting device, creates light emission from one subset of stripes. Reversing the polarity of the applied dc voltage creates light emission from the second subset of organic light emitting devices. Applying an ac driving voltage with an amplitude of more than 2, 5 V and a frequency of more than 50 Hz may light up the total structure with green or yellow emission.

It should be understood that FIG. 6 depicts only one possible circuit arrangement of a whole variety of possible circuit arrangements of organic light emitting devices according to the present invention. Realization of a circuit arrangement of organic light emitting devices according to FIG. 6, however, will lead to an array of organic light emitting devices, which can be driven by an ac driving voltage and will emit light on both the positive and the negative cycle of the ac driving voltage.

FIG. 7 depicts a circuit arrangement of organic light emitting devices according to an exemplary embodiment of the present invention, wherein a first land a second 2 organic light emitting device are stacked vertically, forming a component 50.

The first 1 and the second 2 organic light emitting devices are stacked such that the forward directions of the first and the second organic light emitting devices point in one direction. The forward directions of first and second organic light emitting devices in FIGS. 7, 8 and 9 are indicated by the diode symbol. The stacked device is produced by a method according to an exemplary embodiment of the present invention, which is described in FIG. 4 in more detail. The lower side of the first organic light emitting device 1 and the upper side of the second organic light emitting device 2 is electrically contacted to a first electrode 3. The upper side of the first organic light emitting device 1 and the lower side of the second organic light emitting device 2 is electrically contacted to a second electrode 4.

FIG. 8 shows a schematic representation of a circuit arrangement of organic light emitting devices according to an exemplary embodiment of the present invention, wherein the circuit arrangement comprises a plurality of components 50, which are described in more detail in FIG. 7. In the exemplary embodiment depicted in FIG. 8, four components 50, 51, 52 and 53 are arranged vertically, such that the forward directions of the four components 50,, 51, 52 and 53 point in substantially the same direction. The first electrode 34 of component 53 is electrically connected to the second electrode 42 of the next upper component 52. The first electrode 33 of the second component 52 is electrically connected to the second electrode 43 of the third component 51. The first electrode 32 of the third component 51 is electrically connected to the second electrode 44 of the fourth and top component 50. The first electrode 41 of the top component 50 is electrically connected to one output of an ac voltage source 30 via electrode 3, while the second electrode 41 of the lowest component 53 is electrically connected to the second output of the voltage source 30 via electrode 4. Voltage source 30 may be an ac voltage source.

By serially connecting the four stacked components in the above described way, the driving voltage from the ac driving voltage source 30 is split among the four components. Therefore, the overall breakthrough voltage of the circuit arrangement may be four times higher than the individual breakthrough voltage of each component. In other words, by serially connecting a plurality of components according to an exemplary embodiment of the present invention, no transformation of the driving voltage towards lower voltages is needed, since there will be light emission from the circuit arrangement at any time of the ac voltage cycle.

FIG. 9 depicts a circuit arrangement of organic light emitting devices according to an exemplary embodiment of the present invention, comprising three components 50, 51 and 52, which are described in FIG. 7 in greater detail. In an exemplary embodiment of the present invention, the three components are arranged on a transparent substrate 14 as described in FIG. 6. The first electrode 3 of the third component 52 is electrically connected to an ac voltage source 30, whereas the second electrode 43 of the third component 52 is electrically connected to the first electrode 31 of the second component 51. The second electrode 42 of the second component 51 is electrically connected to the first electrode 32 of the first component 50. The second electrode 41 of the first component 50 is electrically connected to a ground potential 40 via second electrode 4. It should be understood that each component may comprise different organic layers, emitting different wave lengths of radiation and therefore emitting light of different colours.

Thus, according to the present invention, due to the fact that no separate or extra rectifier is needed, smaller, cheaper and more efficient light emitting devices may be provided.

1. Circuit arrangement of organic diodes, comprising:
a first organic diode;
a second organic diode; wherein the organic diodes are electrically contacted to electrodes such that: on a positive cycle of an ac driving voltage, the first organic diode is operated in forward direction and the second organic diode is reversely biased; and on a negative cycle of the ac driving voltage, the first organic diode is reversely biased and the second organic diode is operated in a forward direction.

2. Circuit arrangement according to claim 1, wherein the first and second organic diodes are first and second organic light emitting devices.

3. Circuit arrangement according to claim 2, comprising: an array of first and second organic light emitting devices, the array emitting light on the negative and the positive cycle of the ac driving voltage; wherein the first and second organic light emitting devices each comprise a lower side and an upper side; wherein the first and second organic light emitting devices are stacked vertically; wherein the first and second organic light emitting devices are stacked such that the forward directions of the first and second organic light emitting devices substantially point in one direction; wherein the lower side of the first organic light emitting device and the upper side of the second organic light emitting device are electrically contacted to a first electrode; and wherein the upper side of the first organic light emitting device and the lower side of the second organic light emitting device are electrically contacted to a second electrode.

4. Circuit arrangement according to claim 2, wherein the first and second organic light emitting devices emit light of a colour selected from the group of colours consisting of blue, green, yellow, and red.

5. Circuit arrangement according to claim 3, wherein one first organic light emitting device and one second organic light emitting device form a component; wherein a plurality of components is arranged one of vertically and horizontally; wherein, when arranged vertically, the first electrode of each component is electrically connected to the second electrode of the next upper component in such way, that all components are connected in series; wherein, when arranged horizontally, the first electrode of each component is electrically connected to the second electrode of an adjacent component in such a way, that all components are connected in series.

6. Method for producing a circuit arrangement of organic light emitting devices, wherein the circuit arrangement is arranged on a substrate, the method comprising the steps of:
depositing a first layer on a structured electrode, the layer comprising α-NPD;
depositing a second layer on the first layer, the second layer comprising CBP:FIrpic;
depositing a layer third layer on the second layer, the third layer comprising BAlq;
depositing a fourth layer on the third layer, the fourth layer comprising Bphen: Cs;
depositing a fifth layer on the fourth layer, the fifth layer comprising Ag;
depositing a sixth layer on the fifth layer, the sixth layer comprising α-NPD;
depositing a seventh layer on the sixth layer, the seventh layer comprising CBP:FIrpic;
depositing an eighth layer on the seventh layer, the eighth layer comprising BAlq;
depositing a ninth layer on the eighth layer, the ninth layer comprising Bphen: Cs;
depositing a tenth layer on the ninth layer, the tenth layer comprising Al; and
electrically contacting the organic light emitting devices formed with the first to tenth layer to first and second electrodes.

7. Method according to claim 6, wherein the thickness of the first layer is approximately 30 nm; wherein the thickness of the second layer is approximately 80 nm; wherein the thickness of the third layer is approximately 30 nm; wherein the thickness of the fourth layer is approximately 5 nm; wherein the thickness of the fifth layer is approximately 10 nm; wherein the thickness of the sixth layer is approximately 30 nm; wherein the thickness of the seventh layer is approximately 80 nm; wherein the thickness of the eighth layer is approximately 30 nm; and wherein the thickness of the ninth layer is approximately 5 nm;

8. Method according to claim 6, wherein the dopant concentration of the second layer is approximately 8%; and wherein the dopant concentration of the seventh layer is approximately 8%.

9. Method for producing a circuit arrangement of organic light emitting devices, wherein the circuit arrangement is arranged on a transparent substrate, the substrate comprising a structured electrode, the method comprising the steps of:
depositing a first layer on the structured electrode, the first layer comprising PDOT;
depositing a second layer on the first layer, the second layer comprising a light emissive polymer, preferably the light emissive polymer is PPV;
depositing a third layer on the second layer, the third layer being structured and comprising Ba;
depositing a fourth layer on the third layer, the fourth layer being structured and comprising Al; and
electrically contacting the organic light emitting devices formed with the first to fourth layers to first and second electrodes.

10. Method according to claim 9, wherein the thickness of the first layer is approximately 150 nm; wherein the thickness of the second layer is approximately und 70 nm; wherein the thickness of the third layer is approximately 5 nm; and wherein the thickness of the fourth layer is approximately 150 nm,
